(19) United States
(12) Patent Application Publication
(10) Pub. No.: US 2026/0145277 A1
(43) Pub. Date: May 28, 2026

(54) LASER PROCESSING METHOD AND MANUFACTURING METHOD FOR CHIPS

(71) Applicant: DISCO CORPORATION, Tokyo (JP)

(72) Inventor: Yuki IKEDA, Tokyo (JP)

(21) Appl. No.: 19/371,219

(22) Filed: Oct. 28, 2025

(30) Foreign Application Priority Data
Nov. 27, 2024 (JP) 2024-206603

(51) Int. Cl. B23K 26/60; B23K 26/082; B23K 26/382; B23K 26/70; B23K 101/40; H01L 21/78

(52) U.S. Cl. CPC B23K 26/60; B23K 26/0821; B23K 26/382; B23K 26/702; H10P 54/00; B23K 2101/40

(57) ABSTRACT

Provided is a laser processing method of irradiating a workpiece with a laser beam. The laser processing method makes the laser beam incident on a reflecting surface of a rotating polygon mirror, and irradiates the workpiece with the laser beam reflected by the reflecting surface, to thereby form a plurality of first processing marks which are arranged along a processing feed direction and do not overlap with each other on the workpiece, and, after formation of the first processing marks, makes the laser beam incident on a reflecting surface of the rotating polygon mirror, and irradiates the workpiece with the laser beam reflected by the reflecting surface, to thereby form a plurality of second processing marks which are arranged along the processing feed direction and do not overlap with each other on the workpiece.

### BACKGROUND OF THE INVENTION

### Field of the Invention

The present invention relates to a method of applying a laser beam to a workpiece including a semiconductor and the like as a base material to process the workpiece. In addition, the present invention relates to a manufacturing method for chips, the method of applying a laser beam to a workpiece including a semiconductor and the like as a base material to divide the workpiece into chips.

### Description of the Related Art

Device chips such as integrated circuits (ICs) are components required for electronic equipment such as mobile phones and personal computers. In a manufacturing process for device chips, a plurality of streets (dividing lines) are set on a front surface of a wafer in a grid shape, and devices are formed in a plurality of respective regions demarcated by the streets, and then, the wafer is divided into individual pieces along the streets, so that device chips thus singulated are obtained.

For division of the wafer, for example, a method called laser ablation processing is used. In the laser ablation processing, a laser beam of a wavelength absorbable by a material of the workpiece is applied to the workpiece, and the material of an irradiated part is evaporated by its energy and removed, and thus, grooves are formed in a front surface of the workpiece, or the workpiece is cut.

As a related-art technique reciting a technique regarding laser ablation processing described above, for example, there are Japanese Patent Laid-open No. 2003-320466, Japanese Patent Laid-open No. 2024-16594, and the like.

In the laser ablation processing described above, a pulsed laser that emits laser beams with a constant period is generally used. In a case in which laser ablation processing is performed on the workpiece in a linear manner, for example, first, by the first pulse, the laser beam is applied to the workpiece for a very short period of time, and a processing mark in a dot shape is formed on the workpiece. Subsequently, by the second pulse, the laser beam is applied to the workpiece at a position adjacent to the first processing mark to form a next processing mark. The first processing mark and the second processing mark partially overlap with each other, and the irradiation with the laser beam is repeated, so that processing marks including a large number of spot-like processing marks arranged in a successive form are linearly formed on the workpiece.

In a process using such laser ablation processing, in order to improve the productivity, for example, it is considerable to increase a formation rate of the processing marks by increasing a repetition frequency of a laser beam to be applied and increasing the irradiation number of the laser beam per unit time.

However, if the repetition frequency of the laser beam is increased, the effect of heat remaining after the irradiation with the laser beam cannot be ignored. If the repetition frequency of the laser beam is higher, a time between the application of the first laser beam to a certain position of the workpiece and the application of the subsequent laser beam to a position adjacent to the previous one is further reduced. As a result, in a state in which heat remains around the first processing mark, the subsequent laser beam is applied to the periphery thereof, and consequently, the condition of the workpiece at the periphery of the processing mark becomes deteriorated.

### SUMMARY OF THE INVENTION

Accordingly, an object of the present invention is to provide a laser processing method and a manufacturing method for chips that are capable of suppressing deterioration in processing quality by preventing heat from being accumulated in a workpiece at a time of laser processing.

In accordance with an aspect of the present invention, there is provided a laser processing method of applying a laser beam to a workpiece, including making a laser beam incident on a reflecting surface of a rotating polygon mirror, and irradiating the workpiece with the laser beam reflected by the reflecting surface, thereby forming a plurality of first processing marks which are arranged along a processing feed direction and do not overlap with each other on the workpiece, and after formation of the first processing marks, making a laser beam incident on a reflecting surface of the rotating polygon mirror, and irradiating the workpiece with the laser beam reflected by the reflecting surface, thereby forming a plurality of second processing marks which are arranged along the processing feed direction and do not overlap with each other on the workpiece.

According to the aspect of the present invention, preferably, each of the plurality of second processing marks overlaps with any of the plurality of first processing marks at least in part.

According to the aspect of the present invention, preferably, in a case in which one processing mark and another processing mark overlap with each other at least in part or are adjacent to each other, irradiation of the laser beam for forming the other processing mark is not performed at a time interval of less than 100 microseconds from irradiation of the laser beam for forming the one processing mark.

According to the aspect of the present invention, preferably, a width of each of the plurality of first processing marks along the processing feed direction and a distance between centers of the plurality of first processing marks along the processing feed direction are equal to each other.

According to the aspect of the present invention, preferably, the laser processing method further includes, before formation of the first processing mark, applying a laser beam to the workpiece to form a preliminary processing mark, after formation of the preliminary processing mark and before formation of the first processing mark, measuring a width of the preliminary processing mark along the processing feed direction, and after measurement of the width of the preliminary processing mark and before formation of the first processing mark, setting at least any of a value regarding a repetition frequency of the laser beam in formation of the first processing mark and formation of the second processing mark, a value regarding a rotation speed of the polygon mirror, or a value regarding a relative moving speed between the workpiece and the polygon mirror along the processing feed direction according to the width of the preliminary processing mark along the processing feed direction. In a case in which the value regarding relative moving speed between the workpiece and the polygon mirror is set, in at least any timing of during formation of the first processing mark, during formation of the second processing mark, or between formation of the first processing mark and formation of the second processing mark, moving the workpiece and the polygon mirror relative to each other along the processing feed direction.

According to the aspect of the present invention, preferably, grooves are formed in the workpiece by performing ablation on the workpiece with the laser beam.

According to the aspect of the present invention, preferably, the workpiece includes gallium arsenide.

In accordance with another aspect of the present invention, there is provided a manufacturing method for chips, dividing a workpiece into a plurality of chips, includes making a laser beam incident on a reflecting surface of a rotating polygon mirror, and irradiating the workpiece with the laser beam reflected by the reflecting surface, thereby forming a plurality of first processing marks which are arranged along a processing feed direction and do not overlap with each other on the workpiece, and after formation of the first processing marks, making a laser beam incident on a reflecting surface of the rotating polygon mirror, and irradiating the workpiece with the laser beam reflected by the reflecting surface, thereby forming a plurality of second processing marks which are arranged along the processing feed direction and do not overlap with each other on the workpiece.

According to the laser processing method and the manufacturing method for chips relating to the aspects of the present invention, when laser processing is performed, by moving the irradiation position of the laser beam on the workpiece by the polygon mirror, a plurality of first processing marks which do not overlap with each other are formed on the workpiece, and then, a plurality of second processing marks which do not overlap with each other are formed on the workpiece. In this manner, heat accumulation in the workpiece is prevented, and the deterioration in processing quality can be suppressed.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically depicting an example of an overall configuration of a laser processing apparatus;

FIG. 2 is a perspective view depicting one example of a form of a workpiece;

FIG. 3 is a schematic view depicting an example of a configuration of a laser beam applying unit;

FIG. 4 is a schematic view depicting an example of movement of a position of a irradiation spot along streets of the workpiece in laser processing as a reference example;

FIG. 5 is a schematic view depicting an example of a relation between an angle of a reflecting surface of a polygon mirror and a direction of travel of a laser beam;

FIG. 6A is a schematic view depicting an example of movement of positions of irradiation spots along the street of the workpiece in laser processing as a working example, and positions of irradiation spots due to reflection by one surface (first surface) of the reflecting surfaces of the polygon mirror;

FIG. 6B is a schematic view depicting an example of movement of positions of irradiation spots along the street of the workpiece in laser processing as another working example, and positions of irradiation spots due to reflection by a second surface adjacent to the first surface of the reflecting surfaces of the polygon mirror; and

FIG. 7 is a flowchart describing an example of procedures according to the laser processing method and the manufacturing method for chips.

### DETAILED DESCRIPTION OF THE PREFERRED EMBODIMENT

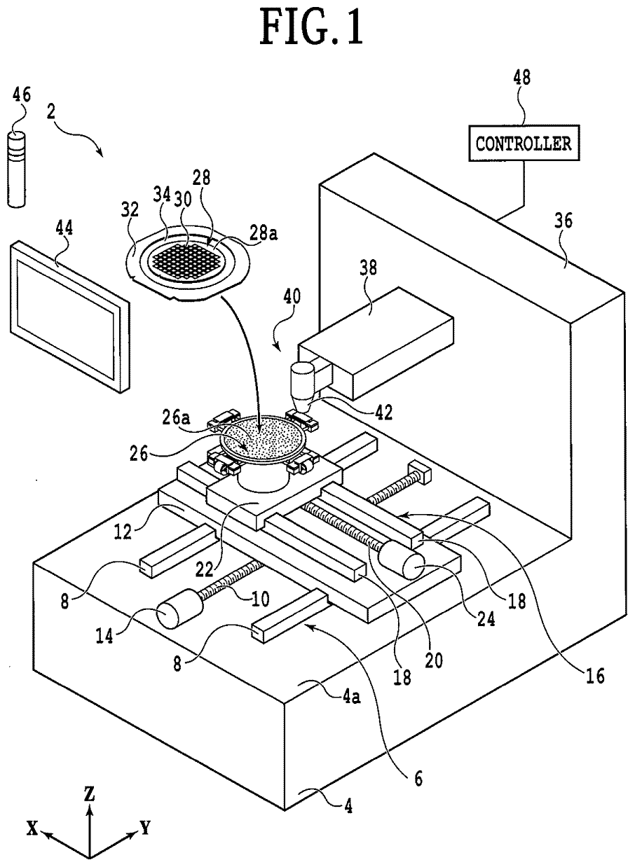

Hereinafter, an embodiment according to the present invention will be described with reference to the attached drawings. First, a configuration example of a laser processing apparatus according to the present embodiment will be described. FIG. 1 is a perspective view schematically depicting an example of an overall configuration of a laser processing apparatus 2.

In FIG. 1, an X direction, a Y direction, and a Z direction indicate orientations of three axes which are perpendicular to one another in a three-dimensional space. The X direction (right-left direction) and the Y direction (front-rear direction) are horizontal directions perpendicular to each other. The Z direction (up-down direction) is an orientation that is perpendicular to the X direction and the Y direction and is a vertical direction. In addition, in the laser processing apparatus 2 according to the present embodiment, an orientation along the X direction is set as a processing feed direction, and an orientation along the Y direction is set as an index feed direction.

It is to be noted that, although such expressions as “along the X direction” or “along the XY plane” are used in the present specification, they do not necessarily refer to only a case in which orientations and movements of members or light rays are matched with or parallel to these axes or planes. For example, such expressions include a case in which the members or the light rays form slightly oblique angles relative to each other but they are oriented in substantially the same direction, a case in which the angles formed by the members or the light rays or the movements thereof include a component in the relevant direction, or the like.

The laser processing apparatus 2 includes a base 4 which supports components of the laser processing apparatus 2, and the components (a moving system (a Y-axis moving unit 6 and an X-axis moving unit 16), a holding table (chuck table) 26, a laser beam applying unit 40) held on the base 4.

An upper surface 4a of the base 4 forms a plane extending along the horizontal plane (XY plane), and the Y-axis moving unit 6 and the X-axis moving unit 16 as the moving unit are attached onto the upper surface 4a.

The Y-axis moving unit 6 includes a Y-axis guide rails 8, a ball screw 10, a Y-axis moving table 12, and a rotational drive source 14.

The Y-axis guide rails 8 are a pair of rod-like members disposed in parallel to each other along the Y direction on the upper surface 4a of the base 4. The ball screw 10 is disposed between the pair of Y-axis guide rails 8 along a longitudinal direction of the Y-axis guide rails 8. The Y-axis moving table 12 in a plate-like shape is slidably mounted on an upper portion of the pair of Y-axis guide rails 8 along the Y-axis guide rails 8.

On a side of a back surface (lower surface) of the Y-axis moving table 12, a nut section (not depicted) is provided, and the ball screw 10 penetrates this nut section. An end of the ball screw 10 has a rotational drive source 14 such as a pulsed motor coupled therewith, and while, owing to operation of the rotational drive source 14, the ball screw 10 is rotated about its axis as a center, the Y-axis moving table 12 moves along the Y-axis guide rails 8.

The X-axis moving unit 16 includes X-axis guide rails 18, a ball screw 20, an X-axis moving table 22, and a rotational drive source 24.

The X-axis guide rails 18 are a pair of rod-like members disposed parallel to each other along the X direction on the Y-axis moving table 12. The ball screw 20 is disposed along the longitudinal direction of the X-axis guide rails 18 between the pair of X-axis guide rails 18. The X-axis moving table 22 in a plate-like shape is slidably mounted along the X-axis guide rails 18 on an upper portion of the pair of X-axis guide rails 18.

On a side of a back surface (lower surface) of the X-axis moving table 22, a nut section (not depicted) is provided, and the ball screw 20 penetrates the nut section. An end of the ball screw 20 has a rotational drive source 24 such as a pulsed motor coupled therewith, and while, owing to operation of the rotational drive source 24, the ball screw 20 is rotated about its axis as a center, the X-axis moving table 22 moves along the X-axis guide rails 18.

The chuck table 26 serving as the holding table is attached onto the X-axis moving table 22. The chuck table 26 is a table for holding the workpiece 28 that is an object to be subjected to laser processing by the laser processing apparatus 2.

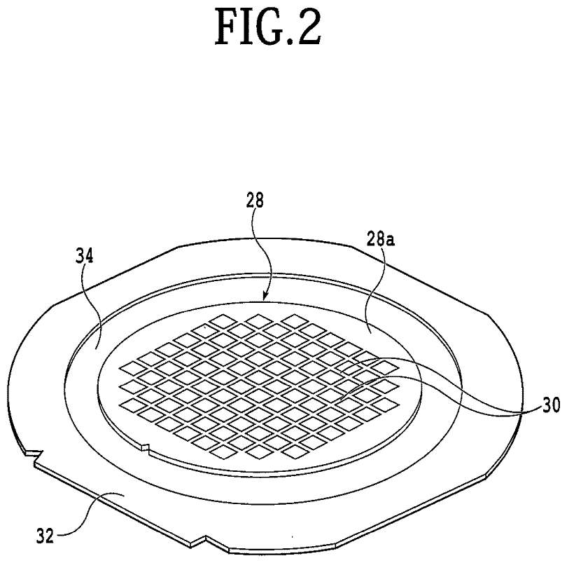

Here, the workpiece 28 will be described. FIG. 2 is a perspective view depicting one example of a form of the workpiece 28. The workpiece 28 is, for example, a disc-shaped wafer including a semiconductor material such as gallium arsenide or a single crystal silicon.

The workpiece 28 in a disc-like shape is demarcated into a plurality of rectangular regions crossing each other by a plurality of streets (dividing lines) 30 arrayed in a grid shape. On a front surface 28a side of each of the regions demarcated by the streets 30, a device such as an IC, a large scale integration (LSI), a light emitting diode (LED), or a micro electro mechanical systems (MEMS) device is formed.

However, a type, a material, a shape, a structure, a size, and the like of the workpiece 28 are not limited to any particular ones. For example, the workpiece 28 may be formed by a substrate (wafer) including a semiconductor (InP, GaN, SiC, or the like) other than gallium arsenide or silicon, sapphire, glass, ceramic, resin, or metal as a base material. In addition, a type, a number, a shape, a structure, a size, arrangement, and the like of the device to be formed on the front surface 28a of the workpiece 28 are also not limited to any particular ones, and any devices may not be formed in the workpiece 28.

When the workpiece 28 is handled with an apparatus such as the laser processing apparatus 2 (see FIG. 1) or the like, for the convenience of transfer, holding, or the like, the workpiece 28 is supported by such a frame 32 depicted in FIG. 2. The frame 32 is, for example, a plate-shaped member including metal such as stainless steel (SUS), and a circular opening penetrating the frame 32 in a thickness direction is provided in a center portion of the frame 32. A diameter of this opening is set larger than that of the workpiece 28.

The workpiece 28 and the frame 32 have a sheet 34 attached thereto. As the sheet 34, for example, a tape including a film-shaped base material layer which is formed into a circular shape and an adhesive layer (glue layer) provided on the base material layer is used. The base material layer includes a resin such as polyolefin, polyvinyl chloride, or polyethylene terephthalate. In addition, the adhesive layer is made of an epoxy-, acrylic-, or rubber-based adhesive or the like. The adhesive layer may be formed of ultraviolet curable resin.

In a state in which the workpiece 28 is disposed inside the opening of the frame 32, a center portion of the sheet 34 is adhered to one side of the workpiece 28, and an outer peripheral portion of the sheet 34 is adhered to one side of the frame 32. Accordingly, the workpiece 28 is supported by the frame 32 through the sheet 34.

As depicted in FIG. 1, an upper surface 26a of the chuck table 26 forms a flat surface along the horizontal plane (XY plane) and constitutes a holding surface for holding the workpiece 28. The upper surface (holding surface) 26a is connected to a suction source such as an ejector (not depicted) through a flow channel (not depicted), a valve (not depicted), or the like, which are formed in the chuck table 26.

Moreover, a rotational drive source (not depicted), such as a motor, for rotating the chuck table 26 about a rotational axis along the vertical direction (Z direction), is coupled with a lower portion of the chuck table 26. Accordingly, the chuck table 26 is rotated relative to the X-axis moving table 22 with an axis along the vertical direction (Z direction) as a center.

When the rotational drive source 14 of the Y-axis moving unit 6 is operated, the chuck table 26 moves with the Y-axis moving table 12 and the X-axis moving unit 16 along the Y direction. When the rotational drive source 24 of the X-axis moving unit 16 is operated, the chuck table 26 moves with the X-axis moving table 22 along the X direction.

Owing to the moving system (Y-axis moving unit 6 and X-axis moving unit 16), the chuck table 26 and the laser beam applying unit 40 move relative to each other in orientations along the Y axis and the X axis. Here, it is to be noted that, as a system for moving the chuck table 26 and the laser beam applying unit 40 relative to each other, a system for moving the chuck table 26 relative to the laser beam applying unit 40 has been described, but in place of the system for moving the chuck table 26 or in addition thereto, a system for moving the laser beam applying unit 40 may be included in the laser processing apparatus 2.

A support structure 36 is provided at a position of the base 4 on the far side as viewed from the side of the moving system (Y-axis moving unit 6 and X-axis moving unit 16) and the chuck table 26, in such a manner as to protrude from the upper surface 4a to the upper side. The support structure 36 is a wall-like structural body provided on the upper surface 4a of the base 4, and a front surface of the support structure 36 forms a plane along an XZ plane. A bar-shaped support member 38 protruding toward the front side is attached to the front surface of the support structure 36.

The support member 38 has a laser processing head 42 as a component of the laser beam applying unit 40 attached thereto. The laser beam applying unit 40 is a system for generating a laser beam and applying the laser beam to the workpiece 28 held on the holding table (chuck table) 26. The laser processing head 42 is a component of the laser beam applying unit 40 having a function of focusing the laser beam and applying the focused laser beam to the workpiece 28.

The support member 38 extends from the support structure 36 to a region above the chuck table 26, and the laser processing head 42 is mounted at a distal end portion of the support member 38.

An imaging unit (not depicted) may be provided at the distal end portion of the support member 38. The imaging unit includes an image sensor such as a charged-coupled device (CCD) sensor or a complementary metal-oxide-semiconductor (CMOS) sensor, and captures an image of the workpiece 28 held on the chuck table 26, or the like. According to an image acquired by the imaging unit, for example, alignment between the workpiece 28 and the laser processing head 42, and the like, are performed. The imaging unit adopts, for example, a visible-light camera or an infrared camera, and is not limited to any particular type, system, and the like.

The support member 38 may be connected to the support structure 36 through a Z-axis moving unit (not depicted) which moves the support member 38 up and down along the Z-axis direction. For example, a moving system of a ball screw type is provided as the Z-axis moving unit on a front surface of the support structure 36. In this case, by causing the Z-axis moving unit to move the support member 38 up and down along the Z-axis direction, adjusting in height position of a focused spot of the laser beam applied from the laser processing head 42 and focusing of the imaging unit are performed.

It is to be noted that the Z-axis moving unit may be so configured as to move the chuck table 26, the laser processing head 42, or part thereof relative to one another along the Z direction, and may be so configured as to move, for example, the laser processing head 42 or part thereof in a up-down direction at the distal end of the support member 38. Alternatively, the Z-axis moving unit may be so configured as to move the chuck table 26 in the up-down direction.

The laser processing apparatus 2 includes a display unit 44 which displays various types of information regarding operation of the laser processing apparatus 2. As the display unit 44, for example, a touch panel display is used. In a case in which the display unit 44 is a touch panel display, for example, information regarding an operation status of each component of the laser processing apparatus 2 as well as an operation screen for inputting information to the laser processing apparatus 2 are displayed on the display unit 44, and an operator can input information to the laser processing apparatus 2 by a touch operation on the operation screen. In other words, in this case, the display unit 44 functions as an input unit for inputting various types of information to the laser processing apparatus 2 as well.

It is to be noted that the input unit may be an input device such as a mouse or a keyboard which are independently and separately provided from the display unit 44.

In addition, the laser processing apparatus 2 includes a notification unit 46 for notifying an operator of particular information. The notification unit 46 is, for example, an indicator lamp, and is continuously energized or blinks when the laser processing apparatus 2 malfunctions, notifying an operator of an error.

However, a type, a system, and the like of the notification unit 46 are not limited to any particular ones. For example, the notification unit 46 may be a speaker which notifies the operator of information by sound. Alternatively, the display unit 44 may function as the notification unit.

Moreover, the laser processing apparatus 2 includes a controller 48 which controls the laser processing apparatus 2. The controller 48 monitors and controls the components of the laser processing apparatus 2 and is connected to the components of the laser processing apparatus 2 (the moving system (the Y-axis moving unit 6 and the X-axis moving unit 16), the holding table (the chuck table) 26, the laser beam applying unit 40, the display unit 44, the notification unit 46, and the like). The controller 48 inputs a control signal to the components of the laser processing apparatus 2.

The controller 48 includes a computer, for example. More specifically, the controller 48 includes a processing unit which executes computation processing or the like required for operation of the laser processing apparatus 2, and a storing unit which stores various types of information (data, a program, or the like) to be used for operation of the laser processing apparatus 2. The processing unit includes a processor such as a central processing unit (CPU). In addition, the storing unit includes a memory such as a read only memory (ROM) or a random access memory (RAM).

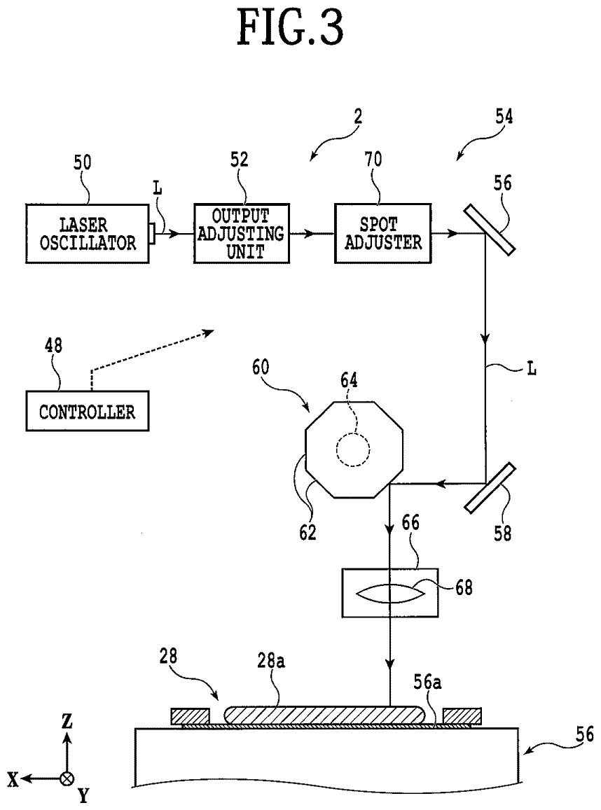

Next, details of the laser beam applying unit 40 will be described. FIG. 3 is a schematic view depicting an example of a configuration of the laser beam applying unit 40. The laser beam applying unit 40 includes not only the laser processing head 42, but also a laser oscillator 50, an output adjusting unit 52, and an optical system 54, and applies the laser beam L to the workpiece 28, thereby subjecting the workpiece 28 to laser processing such as ablation processing.

The laser oscillator 50 is, for example, an yttrium aluminum garnet (YAG) laser, an yttrium orthovanadate (YVO₄) laser, or an yttrium lithium fluoride (YLF) laser, and oscillates the laser beam L by pulse oscillation. The output adjusting unit 52 is, for example, an attenuator. The laser beam L emitted from the laser oscillator 50 enters the output adjusting unit 52, and output power of the laser beam L is adjusted to be emitted from the output adjusting unit 52.

The optical system 54 includes a plurality of optical elements and controls a direction of travel of the laser beam L, a shape of the laser beam L, a position of the focused spot of the laser beam L, and the like. The optical system 54 guides the laser beam L to the workpiece 28 held on the holding table (chuck table) 26.

More specifically, the optical system 54 according to the present embodiment includes mirrors 56 and 58, a polygon mirror 60, a beam condenser 66, and a spot adjuster 70.

The mirrors 56 and 58 are, for example, dielectric multilayered film mirrors. The laser beam L emitted from the output adjusting unit 52 is reflected by reflecting surfaces of mirrors 56 and 58, being incident on the polygon mirror 60.

The polygon mirror 60 is shaped as a polygonal prism having on its outer peripheral side a plurality of flat reflecting surfaces 62 for reflecting the laser beam L. Each of the reflecting surfaces 62 is adjacent to a pair of reflecting surfaces 62, with a side of the polygon mirror 60 in a polygonal prism shape interposed therebetween. In other words, each of the reflecting surfaces 62 is joined to a pair of adjacent reflecting surfaces 62 on both sides thereof.

The polygon mirror 60 has a rotational drive source 64, such as a motor, coupled therewith, and the rotational drive source 64 rotates the polygon mirror 60. A rotational axis of the polygon mirror 60 is set in such a manner to be aligned with an axis direction (the thickness direction and the Y direction) of the polygon mirror 60 shaped as a polygonal prism. Owing to actuation of the rotational drive source 64, the polygon mirror 60 has the rotational axis as a center and is rotated along the XZ plane.

In FIG. 3, the polygon mirror 60 is shaped as an octagonal prism and has eight reflecting surfaces 62. However, the polygon mirror 60 may be of a different shape, and the number of the reflecting surfaces 62 is not limited to this, and the shape and the number of the polygon mirror 60 may be selected depending on the details of laser processing, or the like, as appropriate.

When the laser beam L is applied to the polygon mirror 60 in a state in which the polygon mirror 60 is rotated, the laser beam L is incident on one (irradiated surface) of the reflecting surfaces 62 and is reflected by the irradiated surface. An angle of the irradiated surface changes due to rotation of the polygon mirror 60, according to a timing of incidence of the laser beam L.

Accordingly, a direction of travel of the laser beam L applied to the polygon mirror 60 changes, and a position at which the laser beam L is to be applied is dispersed along the XY plane in a certain region. At a time of applying the laser beam L, the polygon mirror 60 is rotated at high speed, and while the irradiated surface is sequentially switched, the laser beam L is applied to the certain region.

The laser beam L reflected by the reflecting surface 62 of the polygon mirror 60 is applied through the beam condenser 66 to the workpiece 28. The beam condenser 66 includes a focusing lens 68 such as an fθ lens. The laser beam L reflected by the reflecting surface 62 is incident on the beam condenser 66, and the focusing lens 68 focuses the laser beam at a predetermined position (the front surface 28a, the back surface, inside, or the like of the workpiece 28 held on the chuck table 26).

In addition, the optical system 54 according to the present embodiment includes the spot adjuster 70 on an optical path between the output adjusting unit 52 and the mirror 56. The spot adjuster 70 is, for example, a diffractive optical element (DOE) and has a function of splitting the laser beam L to be incident. Hence, a shape of the spot of the laser beam L to be applied to the workpiece 28 changes.

The laser beam L is guided to the workpiece 28 through the various types of optical elements that are the components of the optical system 54 described above. It is to be noted that the configuration of the optical system 54 described above is merely an example, and the type or the number of the optical elements included in the optical system 54 is not limited to any particular one.

For example, the optical system 54 may include a position adjusting unit that adjusts the direction of travel of the laser beam L. The position adjusting unit includes, for example, an acousto-optic deflector (AOD), an electro-optic deflector (EOD), a galvanoscanner, an optical MEMS, or the like, and adjusts, for example, a position to which the laser beam L is to be applied in the Y direction.

The optical system 54 may include a beam shutter (not depicted) that blocks the laser beam L at a suitable position on the optical path of the laser beam L (for example, on an exit side of the position adjusting unit). When the application of the laser beam L to the workpiece 28 is to be stopped, the position adjusting unit adjusts the direction of travel of the laser beam L such that the laser beam L is incident on the beam shutter. Hence, the application of the laser beam L to the workpiece 28 is safely stopped.

In addition, the optical system 54 may further include optical elements such as other mirrors, other lenses, polarizing beam splitters (PBS), or liquid crystal on silicon-spatial light modulator (LCOS-SLM).

The components of the laser beam applying unit 40 (the laser oscillator 50, the output adjusting unit 52, the rotational drive source 64 of the polygon mirror 60, and the like) are connected to the controller 48. The controller 48 inputs a control signal to these components to control operations thereof.

The laser processing method of the workpiece 28 and the manufacturing method for chips by the laser processing apparatus 2 as described above will be described below.

First, as a reference example, movement of the position at which the laser beam L is applied to the workpiece 28 in the conventional laser processing will be described.

The pulse-oscillated laser beam L is applied to the workpiece 28 in a spot-like manner, for each pulse. In the following description, each spot of the laser beam L applied to the workpiece 28 for each pulse is referred to as an irradiation spot.

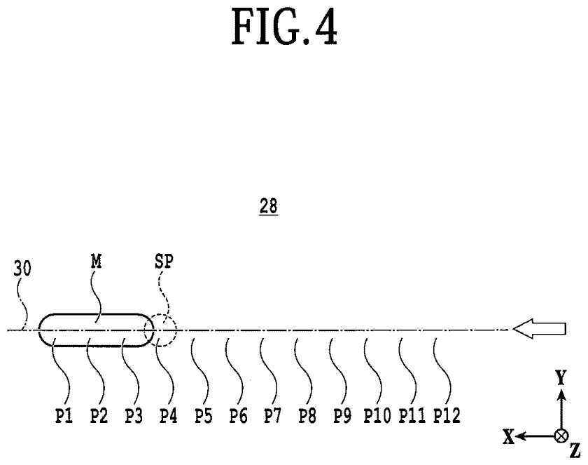

FIG. 4 is a schematic view depicting an example of movement of a position of an irradiation spot along streets 30 of the workpiece 28 in conventional laser processing as a reference example. In the drawing, planned irradiation positions with the laser beam L are indicated with reference signs P1 to P12 along the streets 30 (indicated with a one-dot chain line in the figure) set in the workpiece 28. Numbers 1 to 12 of the reference signs P1 to P12 which are denoted to respective planned irradiation positions are denoted in an order along the orientation of the streets 30.

In the conventional laser processing, for example, each time the laser beam L is pulse-oscillated, the laser beam L is applied to the planned irradiation positions P1 to P12 which are adjacent to each other, in the order of the planned irradiation position P1, the planned irradiation position P2, the planned irradiation position P3, and so on.

FIG. 4 depicts a state in which the laser beam L is applied to the planned irradiation position P4 (a state in which the irradiation spot SP overlaps with the planned irradiation position P4). At this point of time, the laser beam L has already been applied to the planned irradiation positions P1 to P3, and processing marks M have been formed. The processing marks M formed at the respective planned irradiation positions P1 to P3 partially overlap with each other, so that a processing mark in a single linear shape is obtained.

Thereafter, each time the laser beam L is further pulse-oscillated, the position of the irradiation spot SP is moved to the planned irradiation position P5, the planned irradiation position P6, the planned irradiation position P7, and so on, and a new processing mark is formed each time, and as a result, the processing mark M in the figure extends. It is to be noted that, for convenience of explanation, although 12 planned irradiation positions P1 to P12 are depicted here, in practical use, the laser beam L is applied to further more planned irradiation positions along the streets 30, resulting in formation of the processing mark M.

In a case in which the laser beam L is applied along the streets 30 in this manner, after the laser beam L is applied to one of the planned irradiation positions, the laser beam L is applied to another one of the planned irradiation positions that is adjacent to the previous one at an interval of one pulse oscillation period.

Depending on conditions such as the output power of the laser beam L, a period of the pulse oscillation, irradiation time per laser pulse, an application area in the workpiece 28, and the material of the workpiece 28, next application may be performed on adjacent one of the planned irradiation positions while heat generated due to the previous application of the laser beam L remains in the workpiece 28. When next application of the laser beam L is performed in a state in which heat generated due to application of the laser beam L to one of the planned irradiation positions does not sufficiently dissipate, the next application is performed on a portion where the heat remains and therearound. Then, the processing quality may be deteriorated due to excessive heat.

Such a problem can be prevented by, for example, sufficiently increasing the pulse oscillation period. However, the long pulse oscillation period refers to a small number of irradiation with the laser beam per unit of time, and this may inhibit improvement of production efficiency.

In view of this, the inventors of the present application use the polygon mirror 60 to adjust the order of application of the laser beam L to each of the planned irradiation positions, and has come to develop the technique for preventing the abovementioned problem, while using a pulsed laser having a high repetition frequency (whose period is short).

In this method, by appropriately setting operation conditions such as the repetition frequency of the pulse-oscillated laser beam L, the rotation speed of the polygon mirror 60, and a speed of feeding the workpiece 28 along the X direction, a position of each of the irradiation spots of the laser beams L along the X direction is adjusted. This adjustment of the position of the irradiation spot is performed by changing the direction of travel of the laser beam L along the XZ plane with use of the the polygon mirror 60.

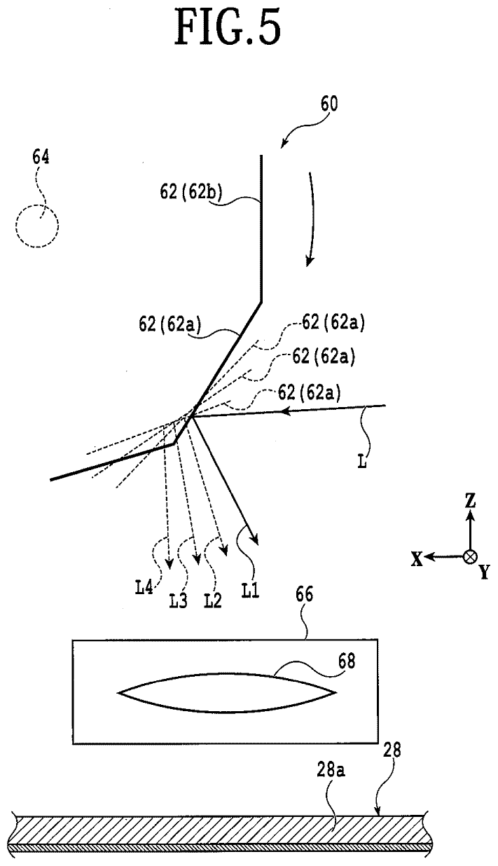

FIG. 5 is a schematic view depicting an example of a relation between an angle of the reflecting surface 62 of the polygon mirror 60 and the direction of travel of the laser beam L. In this figure, the polygon mirror 60 is rotated in a clockwise direction, and the laser beam L is incident on one of the reflecting surfaces 62 (referring to as a first surface 62a for convenience of explanation).

Along with the rotation of the polygon mirror 60, the angle of the first surface 62a is changed, and accordingly, the direction of travel of the laser beam L reflected by the first surface 62a is also changed. A first pulse of the laser beam L, generated by pulse oscillation and incident on the first surface 62a, is reflected by the first surface 62a and travels in a direction (path L1) indicated with a reference sign L1 in the figure. Subsequently, when a second pulse is incident on the first surface 62a, the angle of the first surface 62a has been changed due to the rotation of the polygon mirror 60, so that the second pulse travels in a direction (path L2) different from that of the first pulse after the second pulse is reflected by the the first surface 62a.

Similarly, a third pulse travels along a path L3, and a fourth pulse travels along a path L4. After the fourth pulse is incident on the first surface 62a, due to the rotation of the polygon mirror 60, the reflecting surface (irradiated surface) on which the laser beam L is incident is moved on a second surface 62b adjacent to the first surface 62a. A fifth pulse is reflected by the second surface 62b and travels along the path L1 same as the first pulse. Sixth to eighth pulses are each reflected by the second surface 62b and travel along respective paths L2 to L4.

In this manner, the directions of travel of the laser beams L that are incident on the respective reflecting surfaces 62 of the polygon mirror 60 are sorted into four paths L1 to L4 due to the rotation of the polygon mirror 60.

The laser beam L sorted into each of the paths is applied to the workpiece 28 held on the chuck table 26 positioned below. During application of the laser beam L, the workpiece 28 is moved to an orientation (processing feed direction) along the X direction, by the X-axis moving unit 16.

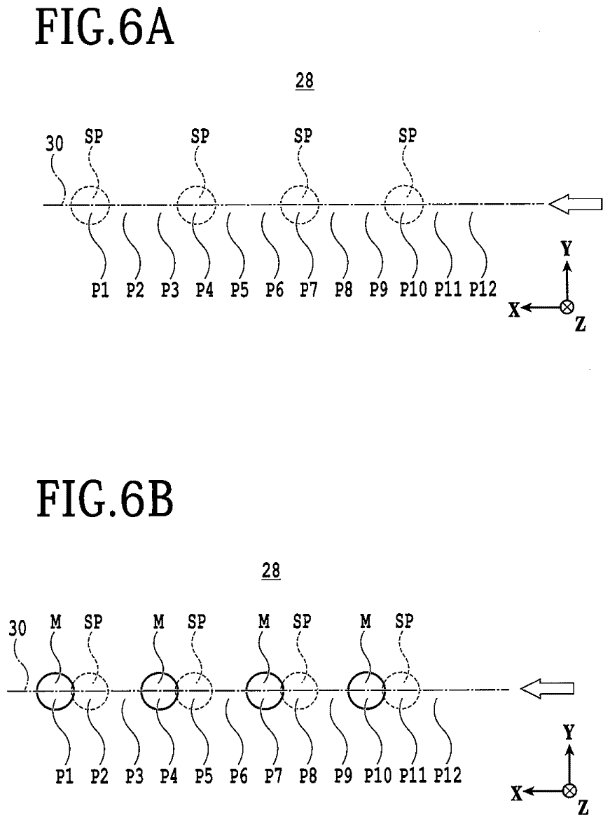

FIGS. 6A and 6B are schematic views each depicting an example of movement of positions of irradiation spots SP along the street 30 of the workpiece 28 in laser processing as a working example. FIG. 6A indicates positions of the irradiation spots SP reflected by the first surface 62a of reflecting surfaces 62 of the polygon mirror 60.

The workpiece 28 is irradiated with the pulse-oscillated laser beam L, while being moved by the X-axis moving unit 16 (see FIG. 1) toward the left direction in the figure. Due to reflection of the first surface 62a (see FIG. 5), the pulses of the laser beams L sorted into the respective paths L1 to L4 irradiate planned irradiation positions P1, P4, P7, and P10, among planned irradiation positions P1 to P12 indicated in FIG. 6A. More specifically, among the planned irradiation positions P1 to P12 depicted in FIG. 6A, the planned irradiation positions P1, P4, P7, and P10 become the irradiation spots SP reflected by the first surface 62a.

At this time, the laser beam L irradiates the planned irradiation position P10, the planned irradiation position P7, the planned irradiation position P4, and the planned irradiation position P1, in this order.

Following four irradiations are performed by reflection of the second surface 62b (see FIG. 5). FIG. 6B depicts the positions of the irradiation spots SP caused by the second surface 62b of the reflecting surface 62 of the polygon mirror 60.

Due to the previous reflection by the first surface 62a, the planned irradiation positions P1, P4, P7, and P10, among the planned irradiation positions P1 to P12, are irradiated with the laser beam L, and accordingly, processing marks M are formed at these positions. Owing to the reflection by the second surface 62b, other planned irradiation positions P2, P5, P8, and P11 which are adjacent to the respective planned irradiation positions P1, P4, P7, and P10 at which the processing marks M have already been formed are irradiated with the laser beam L.

As in the first surface 62a, while four pulse-oscillated laser beams L are sorted into the paths L1 to L4 on the second surface 62b, the X-axis moving unit 16 moves the workpiece 28 during the irradiation with the laser beams L, so that the positions of the irradiation spots SP (see FIG. 6B) attributable to the reflection by the second surface 62b are shifted from the positions of the irradiation spot SP (see FIG. 6A) caused by the reflection by the first surface 62a.

At this time, the laser beam L is applied to the planned irradiation position P11, the planned irradiation position P8, the planned irradiation position P5, and the planned irradiation position P2, in this order.

Here, by appropriately setting conditions such as the repetition frequency of the pulse-oscillated laser beam L, the rotation speed of the polygon mirror 60, a size of the polygon mirror 60 to be used, the number of the reflecting surfaces 62, a size of each of the reflecting surfaces 62, the feed speed of the workpiece 28, the shape of the irradiation spot, and a size of the irradiation spot, the spots obtained by the irradiating the adjacent planned irradiation positions can partially overlap with each other. Alternatively, the irradiation spots can be adjacent to each other (in other words, outer edges thereof can be in contact with each other). As a result, the processing marks are formed in a linear shape along the street 30.

When such laser processing described above is continuously performed, the laser beam L may be applied again to the planned irradiation position to which the laser beam L was once applied. For example, in the examples depicted in FIG. 5, FIG. 6A, and FIG. 6B, some of the irradiation spots obtained by the reflection by the fourth surface (the surface being located three surfaces away from the first surface 62a) overlap with some of the processing marks M formed by the reflection by the first surface 62a.

When laser processing is performed, irradiation with the laser beam L can be performed in multiple times at the same position as described above. Therefore, it is preferable that the conditions such as the output power, wavelength, and the focused position in the Z direction of the laser beam L may be adjusted in advance so as to obtain desired processing marks by the multiple times of irradiation.

Thus, at the time of laser processing, the irradiated position of the laser beam L (the position of the irradiation spot SP) on the workpiece 28 is moved by the polygon mirror 60, and the order of irradiation of the laser beams L onto the planned irradiation positions is adjusted. Accordingly, an interval of the irradiation of the laser beams L between adjacent ones of the planned irradiation positions becomes longer than the period of the pulse oscillation. In other words, the interval of the irradiation of the laser beams L between the adjacent ones of the planned irradiation positions becomes an integer multiple equal to or greater than two of the period of the pulse oscillation.

For example, in the case of such processing depicted in FIG. 6A and FIG. 6B, a time interval of the irradiation of the laser beam L between the planned irradiation position P1 and the planned irradiation position P2 adjacent thereto is four times the period of the pulse oscillation.

In a case in which laser processing is performed as in the reference example of FIG. 4, a time interval of the irradiation of the laser beam L between the planned irradiation position P1 and the planned irradiation position P2 adjacent thereto corresponds to one period of the pulse oscillation. If this period is short, as described above, the laser beam L is applied to the subsequent planned irradiation position P2 in a state in which heat generated by the previous irradiation onto the planned irradiation position P1 has not sufficiently dissipate, and consequently, the processing quality may be degraded.

In contrast, in such processing depicted in FIG. 6A and FIG. 6B, there is a time interval corresponding to four periods of the pulse oscillation between the irradiation onto the planned irradiation position P1 and the irradiation onto the planned irradiation position P2, and accordingly, heat dissipates during the time interval, thereby preventing degradation in processing quality.

It is to be noted that, a case in which the laser beam L is incident on one of the reflecting surfaces 62 four times during one rotation of the polygon mirror 60 is illustrated here, but the incident number of the laser beam L on the reflecting surface 62 varies according to conditions such as the size of the polygon mirror 60, the number of faces of the reflecting surface 62 of the polygon mirror 60, the rotation speed of the polygon mirror 60, and the repetition frequency of pulse oscillation of the laser beam L.

Setting of the condition under which laser processing is performed will be described. The number of rotation of the polygon mirror 60 per one minute is set to N [rpm]. When the number of rotation of the polygon mirror 60 per one second is set to n [rps], a relation n=N/60 is satisfied.

The number of the reflecting surfaces 62 included in the polygon mirror 60 is set to m. In a case in which the polygon mirror 60 is rotated and the laser beam L is incident on the reflecting surface 62 in a state in which the workpiece 28 on the chuck table 26 is not moving, a length of a region of the workpiece 28 on which the laser beam L is incident along the X direction (referred to as a “scan width”) is set to w [mm].

The repetition frequency of the pulse-oscillated laser beam L (referred to as a “laser frequency”) is set to f [Hz]. The feed speed of the chuck table 26 along the X direction is set to v [mm/s]. A feed speed v may take a positive value or a negative value, in association with the orientation of rotation of the polygon mirror 60.

In a case in which the polygon mirror 60 having m reflecting surfaces 62 makes n rotations per one second, the number of times of switching the reflecting surfaces 62 per one second (referred to as a “scan frequency”) is n·m. A period of time required for irradiation (scan) with the laser beam L by one reflecting surface 62 (referred to as a “scan period”) per one rotation of the polygon mirror 60 is 1/(n·m) [s].

When an amount by which the workpiece 28 moves (referred to as a “movement pitch”) is set to p [mm] while scanning by one reflecting surface 62 (first surface 62a) is performed, a relation p=v/(n·m) [mm] is satisfied.

When a travel distance of laser processing per one second along the street 30 is set to D [mm], taking into account the feed speed v of the workpiece 28 by the X-axis moving unit 16, a relation D=n·m⋅w+v [mm] is satisfied. Within a single scan by one reflecting surface, When an average distance between centers of the irradiation spots that are adjacent to each other is set to d [mm], a relation d=D/f [mm] is satisfied.

Parameters such as the numbers of rotations N and n of the polygon mirror 60, the laser frequency f, the feed speed v, the average distance d between the centers of the irradiation spots are adjusted, achieving such laser processing as depicted in FIG. 6A and FIG. 6B.

In view of the above descriptions, a verification test regarding a relation between the processing condition and the processing quality, which has been performed by the inventors of the present application, will be described. In a laser processing apparatus used in this verification test, the number m of the reflecting surfaces of the polygon mirror is 18, and the scan width w is 26.69 [mm], a width of the processing mark formed on the workpiece by a single pulse irradiation of the laser beam is 193 [μm].

In such a laser processing apparatus, other conditions were set to five options as below, and the processing quality under each condition has been verified. In any conditions, the wavelength of the laser beam was set to 1,064 [nm], and the number of rotations N of the polygon mirror was set to 6,000 [rpm]. As the workpiece 28, a wafer including gallium arsenide as a base material was used.
Condition 1: f=150 [Hz], the output power of the laser beam=48 [W], v=587 [mm]
Condition 2: f=200 [kHz], the output power of the laser beam=64 [W], v=440 [mm]
Condition 3: f=250 [kHz], the output power of the laser beam=80 [W], v=400 [mm]
Condition 4: f=400 [kHz], the output power of the laser beam=128 [W], v=440 [mm]
Condition 5: f=600 [kHz], the output power of the laser beam=192 [W], v=440 [mm]

In Condition 1, the average distance d between the centers of the irradiation spots within a single scan by one reflecting surface satisfied a relation d=324 [μm]. This is greater than a width of the processing mark formed by a single pulse irradiation in the processing feed direction (193 [μm]). Hence, the processing mark made by a single pulse irradiation and the processing mark made by the subsequent pulse irradiation do not overlap with each other.

Subsequently, when scanning by another reflecting surface adjacent to the previous reflecting surface is performed, a new processing mark is formed on the workpiece 28 at a position where the workpiece 28 moves by the movement pitch p=326 [μm] from the processing mark formed in the previous scan. The processing mark formed in a single scan by one reflecting surface and the processing mark formed in the subsequent scan by the subsequent reflecting surface partially overlap with each other. This process is repeated, and the processing marks are successively formed along the processing feed direction.

The same applies in Condition 2. In Condition 2, the average distance d between the centers of the irradiation spots within a single scan satisfies a relation d=242 [μm], and this is inevitably greater than the width of the processing mark formed by a single pulse irradiation in the processing feed direction (193 [μm]). Hence, the processing mark formed by a single pulse irradiation and the processing mark formed by the subsequent pulse irradiation do not overlap with each other.

Subsequently, when scanning by another reflecting surface that is adjacent to the previous reflecting surface is performed, a new processing mark is formed on the workpiece 28 at a position where the workpiece 28 moves by the movement pitch p=244 [μm] from the processing mark formed in the previous scan. The processing mark formed by a single scan on one reflecting surface and the processing mark formed in the subsequent scan by the subsequent reflecting surface partially overlap with each other.

In Condition 3, the average distance d between the centers of the irradiation spots within a single scan satisfies a relation d=193 [μm], and this is equal to the width of the processing mark formed by a single pulse irradiation in the processing feed direction (193 [μm]). Hence, the processing mark formed in a single pulse irradiation and the processing mark in the subsequent pulse irradiation do not overlap with each other, but the outer peripheral edges of the relevant two processing marks are in contact with each other. In the subsequent scan, the processing mark is similarly formed at a position where the workpiece 28 moves by the movement pitch p=222 [μm]. In this manner, the processing marks are successively formed along the processing feed direction.

In Condition 4, the average distance d between the centers of the irradiation spots within a single scan satisfies a relation d=121 [μm]. In Condition 5, a relation d=81 [μm] is satisfied. These values are smaller than the width of the processing mark formed by a single pulse irradiation in the processing feed direction (193 [μm]). Hence, the processing mark formed by a single pulse irradiation and the processing mark formed by the subsequent pulse irradiation partially overlap with each other.

As for the workpiece having undergone the laser processing in Conditions 1 to 5 described above, the processing quality around the processing mark was assessed by microscopic observation. As a result, no processing defects caused by heat was observed at the periphery of the processing mark of the workpiece having undergone processing in Conditions 1 and 2. As for the workpiece having undergone processing in Condition 3, processing defects caused by heat were observed at a partial region at the periphery of the processing mark, but the percentage of the relevant region was not large and was an acceptable level. As for the workpiece having undergone processing in Conditions 4 and 5, processing defects caused by heat were observed in the substantially whole region at the periphery of the processing mark.

As described above, in laser processing, it can be considered that the processing condition is preferably adjusted such that a distance between centers of the x-th irradiation spot and the x+1-th irradiation spot is the same as or greater than the width of the processing mark in the processing feed direction.

Here, in a case in which the distance between the centers of the x-th irradiation spot and the x+1-th irradiation spot is the same as the width of the processing mark in the processing feed direction, the processing quality in an acceptable level can be obtained, and since the processing mark continuously extends for each pulse, the production efficiency per unit time may also be improved.

Subsequently, the inventors of the present application conducted an experimental test for verifying appropriate time interval regarding irradiation of the laser beam. In this experimental test, pulses of the laser beams L having the output power of 80 W and a wavelength of 1,064 nm were applied twice to the workpiece including gallium arsenide as a base material, each at different time intervals.

The laser beam L, assuming that an intended width of the processing mark to be formed by the irradiation thereof is 193 [μm], is applied to the workpiece such that the distance between the centers of the processing marks in the width direction becomes 193 [μm] (in other words, such that the width of the processing mark and the distance between the centers of the processing marks become equal to each other).

The time interval between the irradiated pulses is set to three options, 100 [μs], 66 [μs], and 33 [μs]. It is to be noted that these numerals indicate temporal intervals between peaks of the pulses.

After the pulse irradiation, the front surface of the workpiece irradiated with the pulse was subjected to testing by microscopic observation, and as a result, it was observed that the workpiece twice irradiated with the pulses at an interval of 100 [μs] has the processing defects in part but the defects were an acceptable level. It was observed that the workpieces twice irradiated with the pulses at intervals of 66 [μs] and 33 [μs] have the processing defects in the whole of the portions irradiated with the pulses.

As described above, in a case in which the processing with the laser beam L under conditions above is performed on the workpiece at least including gallium arsenide as a base material, if the pulse of the laser beam L is applied to adjacent ones of the planned irradiation positions at a time interval of 100 [μs] or more, it can be considered that preferable processing may be performed suppressing processing defects caused by heat.

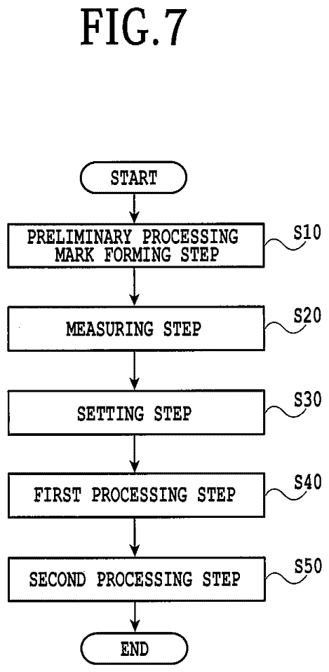

Description regarding procedures of laser processing and a method of manufacturing chips using the abovementioned methods will be given according to the flowchart. FIG. 7 is a flowchart describing an example of procedures according to the laser processing method and the manufacturing method for chips.

The procedures indicated in FIG. 7 include a preliminary processing mark forming step S10, a measuring step S20, a setting step S30, a first processing step S40, and a second processing step S50.

In the preliminary processing mark forming step S10, the laser beam L is applied to the workpiece 28, and a reference processing mark (preliminary processing mark) is formed on the workpiece 28. Here, in such a manner as to discriminate the shape of the processing mark to be formed by a single pulse irradiation of the laser beam L by pulse oscillation, for example, the workpiece 28 held on the chuck table 26 is irradiated with a single pulse. Alternatively, irradiation (a single scan) by one of the reflecting surfaces 62 included in the polygon mirror 60 is performed. The processing mark formed in this manner on the workpiece 28 is a preliminary processing mark.

It is to be noted that the workpiece 28 to be used here may be the same workpiece as the workpiece 28 to be processed in the following first processing step S40 and second processing step S50 and may be, for example, another workpiece including the same base material.

Subsequently, the measuring step S20 is performed. In this measuring step S20, as for the preliminary processing mark formed on the workpiece 28 in the preceding preliminary processing mark forming step S10, the width thereof in the processing feed direction is measured. Measurement of the width can be performed by using an imaging unit (not depicted) attached at a distal end of the support member 38, for example.

The “processing feed direction” is an orientation in which the spots of the laser beams L to be applied to the the workpiece 28 are arranged in the following first processing step S40 and second processing step S50, and in the present embodiment, an orientation along the X direction in FIG. 1 and other figures. The processing feed direction may be set as an orientation along the curve. For example, in a case in which laser processing is performed while the workpiece is rotated, the processing feed direction is an orientation along a circumference of a circle.

The polygon mirror 60 is rotated along a plane (XZ plane) substantially parallel to the processing feed direction. In addition, at the time of performing the laser processing (first processing step S40 and second processing step S50), the workpiece 28 held on the chuck table 26 and the polygon mirror 60 provided in the laser beam applying unit 40 move relative to each other along the processing feed direction.

The shape of the spot (irradiation spot) of the laser beam L applied to the workpiece 28 and the shape of the processing mark formed by the irradiation of the laser beam L on the workpiece 28 can be adjusted by the spot adjuster 70. The shapes of the irradiation spot and the processing mark can be set, for example, to an elliptical shape having a major axis thereof along the processing feed direction.

Subsequently, in the setting step S30, according to the width of the preliminary processing mark in the processing feed direction measured in the measuring step S20, at least any one of values regarding the repetition frequency of the laser beam L, the rotation speed of the polygon mirror 60, or the relative moving speed between the workpiece 28 and the polygon mirror 60 along the processing feed direction in the following first processing step S40 and second processing step S50 is set.

The value regarding the repetition frequency of the laser beam L refers to a value by which the repetition frequency of the laser beam L pulse-oscillated by the laser oscillator 50 can be adjusted by setting the value regarding the repetition frequency of the laser beam L, and, for example, refers to the laser frequency f described above, the pulse period (the inverse of the laser frequency f), or the like.

The value regarding the rotation speed of the polygon mirror 60 refers to the value by which the rotation speed of the polygon mirror 60 can be adjusted by setting the value regarding the rotation speed of the polygon mirror 60, and, for example, refers to the numbers of rotations N and n per unit of time described above, the number of scans per unit of time (the number of switching the reflecting surfaces on which the laser beam L is incident), or the like.

The value regarding the relative moving speed between the workpiece 28 and the polygon mirror 60 along the processing feed direction refers to the value by which the relative moving speed between the workpiece 28 and the polygon mirror 60 along the processing feed direction can be adjusted by setting the value regarding the relative moving speed between the workpiece 28 and the polygon mirror 60 along the processing feed direction, and, for example, refers to the feed speed v of the chuck table 26 by the X-axis moving unit 16.

The setting of these values is input by an operator, for example, through the display unit 44 that is a touch panel display, to the controller 48. Alternatively, according to the measured width of the preliminary processing mark, the controller 48 may automatically set each value by itself.

Subsequently, the first processing step S40 and the second processing step S50 are performed. The workpiece 28 that is an object to undergo laser processing is held on the chuck table 26, and operation of the X-axis moving unit 16 caused the workpiece 28 to move in the processing feed direction. At the same time, the laser beam L emitted from the laser oscillator 52 by pulse oscillation is incident on the reflecting surface 62 of the rotating polygon mirror 60, and the laser beam L reflected by the the reflecting surface 62 irradiates the workpiece 28.

The first processing step S40 and the second processing step S50 can be performed as a successive steps due to the rotation of the polygon mirror 60. For example, the formation of the processing marks (the irradiation of the laser beams L onto the planned irradiation positions P1, P4, P7, and P10 illustrated in FIG. 6A) caused by a series of reflections by one reflecting surface 62 (the first surface 62a in FIG. 5) among the plurality of reflecting surfaces 62 provided in the polygon mirror 60 corresponds to the first processing step S40, and the formation of the processing marks (the irradiation of the laser beams L onto the planned irradiation positions P2, P5, P8, and P11 illustrated in FIG. 6B) caused by a series of reflections by the subsequent reflecting surface 62 adjacent to the previous reflecting surface (the second surface 62b in FIG. 5) corresponds to the second processing step S50.

It is to be noted that, in the example described above, while the first processing step S40 and the second processing step S50 are successively performed, the workpiece 28 and the polygon mirror 60 are moved relative to each other along the processing feed direction. However, in theory, in addition to such a procedure, for example, it is possible to perform processing by a procedure in which the first processing step S40 is performed in a state in which the workpiece 28 and the polygon mirror 60 are stationary with each other, subsequently, the workpiece 28 and the polygon mirror 60 are moved relative to each other along the processing feed direction and brought to rest again, and the second processing step S50 is performed in that state.

More specifically, in a case in which the workpiece 28 and the polygon mirror 60 are moved relative to each other along the processing feed direction, the movement may be performed during the first processing step S40, may be performed during the second processing step S50, may be performed between the first processing step S40 and the second processing step S50, or at a plurality of timings of or in the whole of them. Setting of the moving speed or the timing for the movement can be performed in the setting step S30.

Alternatively, the processes from the first processing step S40 to the second processing step S50 may be performed without involving relative movement between the workpiece 28 and the polygon mirror 60. In that case, for example, by adjusting the rotation speed and the angle or the like of the polygon mirror 60, in such a manner that the irradiation position of the laser beam L in the first processing step S40 and the irradiation position of the laser beam L in the second processing step S50 are different from each other, the irradiation position of the laser beam L may be controlled.

In the first processing step S40, a plurality of processing marks are formed on the workpiece 28 along the processing feed direction. The plurality of processing marks (referred to as first processing marks) do not overlap with each other. In addition, also in the second processing step S50, a plurality of processing marks are formed on the workpiece 28 along the processing feed direction, and the plurality of processing marks (referred to as second processing marks) also do not overlap with each other. In other words, a distance between centers of the processing marks belonging to the first processing marks along the processing feed direction is equal to or greater than the width of each of the processing marks along the processing feed direction. The same applies to each of the processing marks belonging to the second processing marks.

In contrast, the processing marks belonging to the first processing marks and the processing marks belonging to the second processing marks may not overlap with each other, may overlap with each other, or may be adjacent to each other.

In a case in which the distance between the center of each of the processing marks belonging to the first processing marks and the center of each of the processing marks belonging to the second processing marks along the processing feed direction is equal to the width of each of the processing marks along the processing feed direction, the first processing mark and the second processing mark are adjacent to each other.

In a case in which the distance between the center of each of the processing marks belonging to the first processing marks and the center of each of the processing marks belonging to the second processing marks along the processing feed direction is smaller than the width of each of the processing marks along the processing feed direction, the first processing mark and the second processing mark overlap with each other at least in part.

In these cases, in such a manner that a new processing mark is added to the already-formed processing mark, the processing mark further extends along the processing feed direction.

In a case in which the distance between the center of each of the processing marks belonging to the first processing marks and the center of each of the processing marks belonging to the second processing marks along the processing feed direction is greater than the width of each of the processing marks along the processing feed direction, the first processing mark and the second processing mark are spaced apart from each other. In this case, by continuously performing laser processing, the laser beam L is applied to the workpiece 28 so as to bury a portion between these processing marks, and the processing mark is formed in a linear shape along the processing feed direction.

One processing mark formed on the workpiece 28 and another processing mark may overlap at least in part or may be adjacent to each other. In this case, application of the laser beam L to these processing marks may be preferably performed at time intervals sufficient for heat to dissipate adequately. To achieve this, for example, in a case in which the workpiece 28 includes gallium arsenide as a base material, it is preferable that application of the laser beam L to form another processing mark is not performed at a interval of less than 100 microseconds ([μs]) from the application of the laser beam L that forms one processing mark.

According to the examples depicted in FIG. 5, FIG. 6A, and FIG. 6B, for example, it is preferable that a first pulse irradiation by the first surface 62a (pulse irradiation passing through the path L1 and being incident on the planned irradiation position P10) and a first pulse irradiation by the second surface 62b (pulse irradiation passing through the path L1 and being incident on the planned irradiation position P11) may be performed at a time interval of equal to or more than 100 [μs].

A positional relation between the processing marks formed in the first processing step S40 and the second processing step S50, the time intervals between the irradiations of the laser beams L onto the planned irradiation positions, and the like, are adjusted in advance by setting the operation conditions in the setting step S30.

In the processing method as described above, for example, with the use of the laser beam L, the workpiece 28 is subjected to ablation, so that the laser beam L can be used for ablation processing for forming grooves in the workpiece 28. In addition, the laser ablation processing is performed on the entire workpiece 28 in the thickness direction thereof, so that the workpiece 28 can also be divided into individual pieces. The workpiece 28 is divided into a plurality of chips along the streets 30 (see FIG. 2), and accordingly, chips are manufactured.

It is to be noted that, regarding laser processing, a case in which the laser beam L is incident on one reflecting surface 62 in multiple times (four times) per one rotation of the polygon mirror 60 (a case in which the laser beam L is applied to the workpiece 28 four times per one scan) has been descripted above, but the mode of the irradiation of the laser beam L is not limited to this.

For example, the operation conditions such as the repetition frequency of the laser beam L and the rotation speed of the polygon mirror 60 may be adjusted such that the laser beam L is incident on one reflecting surface 62 just once per one rotation of the polygon mirror 60. Alternatively, while the polygon mirror 60 makes one rotation, there may be the reflecting surface 62 on which the laser beam L is not incident. In addition, the directions of travel of the laser beams L after the laser beams L are reflected by the reflecting surface 62 may be different from one another for each reflecting surface 62.

In addition, even in a case in which the laser beam L is incident on one reflecting surface 62 in multiple times for each rotation of the polygon mirror 60, the directions of travel of the laser beams L after reflected on the reflecting surface 62 may be different from one another for each reflecting surface 62.

Further, for example, laser processing may be performed in such a mode that, in a case in which the reflecting surfaces 62 of the polygon mirror 60 adjacent to each other are defined as a first surface, a second surface, a third surface, . . . , an n-th surface along the rotation direction in this order, for example, the processing mark formed on the front surface of the workpiece 28 owing to reflection of the laser beam L by the first surface and the processing mark formed on the front surface of the workpiece 28 owing to reflection of the laser beam L by the second surface do not overlap with each other, and the processing mark formed on the front surface of the workpiece 28 owing to the reflection of the laser beam L by the first surface and the processing mark formed on the the front surface of the workpiece 28 owing to the laser beam L by the reflecting surface 62 that is the third surface or subsequent surfaces overlap with each other.

It is to be noted that, regarding each processing step and the processing marks formed in each step, definitions of the “first processing step,” the “second processing step,” the “first processing mark,” and the “second processing mark” may be changed according to the mode of processing.

For example, in a case in which processing is performed in a mode that the laser beam L is incident on one reflecting surface 62 just once for one rotation of the polygon mirror 60 and the directions of travel of the laser beams L after reflected at the reflecting surface 62 are different for each of the reflecting surfaces 62, the processing due to one rotation of the polygon mirror 60 is defined as the first processing step, and the processing marks formed in this step are defined as the first processing marks. In addition, the processing due to the next rotation of the polygon mirror 60 is defined as the second processing step, and the processing marks formed in this step are defined as the second processing marks. Then, processing may be performed such that the first processing marks may not overlap with each other and the second processing marks may not overlap with each other.

Alternatively, processing by the plurality of reflecting surfaces 62 which are adjacent to each other (for example, processing by the first surface to the third surface) may be defined as the first processing step, and the processing by the plurality of reflecting surfaces 62 subsequent thereto (for example, processing by the fourth surface to the sixth surface) may be defined as the second processing step. Then, processing may be performed such that the first processing marks formed in the first processing step do not overlap with each other, and the second processing marks formed in the second processing step do not overlap with each other.

The present embodiment may be implemented with appropriate modifications within a range not departing from the scope of object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser processing method of applying a laser beam to a workpiece, comprising:
making a laser beam incident on a reflecting surface of a rotating polygon mirror, and irradiating the workpiece with the laser beam reflected by the reflecting surface, thereby forming a plurality of first processing marks which are arranged along a processing feed direction and do not overlap with each other on the workpiece; and
after formation of the first processing marks, making a laser beam incident on a reflecting surface of the rotating polygon mirror, and irradiating the workpiece with the laser beam reflected by the reflecting surface, thereby forming a plurality of second processing marks which are arranged along the processing feed direction and do not overlap with each other on the workpiece.

2. The laser processing method according to claim 1, wherein
each of the plurality of second processing marks overlaps with any of the plurality of first processing marks at least in part.

3. The laser processing method according to claim 1, wherein,
in a case in which one processing mark and another processing mark overlap with each other at least in part or are adjacent to each other, irradiation of the laser beam for forming the other processing mark is not performed at a time interval of less than 100 microseconds from irradiation of the laser beam for forming the one processing mark.

4. The laser processing method according to claim 2, wherein,
in a case in which one processing mark and another processing mark overlap with each other at least in part or are adjacent to each other, irradiation of the laser beam for forming the other processing mark is not performed at a time interval of less than 100 microseconds from irradiation of the laser beam for forming the one processing mark.

5. The laser processing method according to claim 1, wherein
a width of each of the plurality of first processing marks along the processing feed direction and a distance between centers of the plurality of first processing marks along the processing feed direction are equal to each other.

6. The laser processing method according to claim 2, wherein
a width of each of the plurality of first processing marks along the processing feed direction and a distance between centers of the plurality of first processing marks along the processing feed direction are equal to each other.

7. The laser processing method according to claim 1, further comprising:
before formation of the first processing mark, applying the laser beam to the workpiece to form a preliminary processing mark;
after formation of the preliminary processing mark and before formation of the first processing mark, measuring a width of the preliminary processing mark along the processing feed direction; and
after measurement of the width of the preliminary processing mark and before formation of the first processing mark, setting at least any of a value regarding a repetition frequency of the laser beam in the formation of the first processing mark and the formation of the second processing mark, a value regarding a rotation speed of the polygon mirror, or a value regarding a relative moving speed between the workpiece and the polygon mirror along the processing feed direction according to the width of the preliminary processing mark along the processing feed direction, wherein,
in a case in which the value regarding relative moving speed between the workpiece and the polygon mirror is set, in at least any timing of during formation of the first processing mark, during formation of the second processing mark, or between formation of the first processing mark and formation of the second processing mark, moving the workpiece and the polygon mirror relative to each other along the processing feed direction.

8. The laser processing method according to claim 2, further comprising:
before formation of the first processing mark, applying the laser beam to the workpiece to form a preliminary processing mark;
after formation of the preliminary processing mark and before formation of the first processing mark, measuring a width of the preliminary processing mark along the processing feed direction; and
after measurement of the width of the preliminary processing mark and before formation of the first processing mark, setting at least any of a value regarding a repetition frequency of the laser beam in the formation of the first processing mark and the formation of the second processing mark, a value regarding a rotation speed of the polygon mirror, or a value regarding a relative moving speed between the workpiece and the polygon mirror along the processing feed direction according to the width of the preliminary processing mark along the processing feed direction, wherein,
in a case in which the value regarding relative moving speed between the workpiece and the polygon mirror is set, in at least any timing of during formation of the first processing mark, during formation of the second processing mark, or between formation of the first processing mark and formation of the second processing mark, moving the workpiece and the polygon mirror relative to each other along the processing feed direction.

9. The laser processing method according to claim 1, wherein
grooves are formed in the workpiece by performing ablation on the workpiece with the laser beam.

10. The laser processing method according to claim 2, wherein
grooves are formed in the workpiece by performing ablation on the workpiece with the laser beam.

11. The laser processing method according to claim 1, wherein
the workpiece includes gallium arsenide.

12. The laser processing method according to claim 2, wherein
the workpiece includes gallium arsenide.

13. A manufacturing method for chips, dividing a workpiece into a plurality of chips, comprising:
making a laser beam incident on a reflecting surface of a rotating polygon mirror, and irradiating the workpiece with the laser beam reflected by the reflecting surface, thereby forming a plurality of first processing marks which are arranged along a processing feed direction and do not overlap with each other on the workpiece; and
after formation of the first processing marks, making a laser beam incident on a reflecting surface of the rotating polygon mirror, and irradiating the workpiece with the laser beam reflected by the reflecting surface, thereby forming a plurality of second processing marks which are arranged along the processing feed direction and do not overlap with each other on the workpiece.
